(19) United States
(12) Patent Application Publication
(10) Pub. No.: US 2014/0116623 A1
(43) Pub. Date: May 1, 2014

(54) ETCHING TREATMENT APPARATUS

(71) Applicant: LG INNOTEK CO., LTD., Seoul (KR)

(72) Inventor: Ji Hye Kim, Seoul (KR)

(73) Assignee: LG INNOTEK CO., LTD., Seoul (KR)

(21) Appl. No.: 14/123,376

(22) PCT Filed: May 30, 2012
(86) PCT No.: PCT/KR2012/004256

§ 371 Date: Jan. 6, 2014

(30) Foreign Application Priority Data
Jun. 2, 2011 (KR) 10-2011-0053462

(51) Int. Cl. H01L 21/683

(52) U.S. Cl. CPC H01L 21/683
USPC 156/345.51

(57) ABSTRACT

Disclosed is an etching treatment apparatus. The etching treatment apparatus includes a crucible to receive a wafer, a wafer jig part having a groove into which the wafer is seated, and a size adjusting part inserted into the groove while making contact with the edge of the wafer.

### TECHNICAL FIELD

The disclosure relates to an etching treatment apparatus.

### BACKGROUND ART

As the degree of integration of a semiconductor device is increased, the quality of a wafer used to realize the semiconductor device exerts a great influence on the product yield and the reliability of the semiconductor device. The quality of the semiconductor wafer depends on defects occurring throughout the whole processes of growing a crystal and wafering for the fabricating of the wafer. The defects may be mainly classified into a crystal defect caused when growing a silicon ingot and a defect caused by external contaminants.

In general, external contaminants such as dust among the defects of the wafer can be easily removed through an etching process or a cleaning process. However, since crystal defects such as D-defects, oxygen precipitates, lamination defects, and metal precipitates mainly exist when a single crystal is grown, the crystal defects are caused when the single crystal is grown, the crystal defects are not removed through the cleaning process.

In particular, among them, the surface defects of the semiconductor wafer, such as COPs (Crystal Originated Particles) known as micropits, or the D-defects, are not removed through the typical cleaning process, and must be prevented during the manufacturing of the wafer.

The COPs or the D-defects continuously exert an influence even in the process of realizing the semiconductor device on the semiconductor wafer, thereby degrading the product yield or the reliability of the semiconductor device.

Therefore, the checking of exact distribution, the density, and the morphology of the defects before realizing the semiconductor device on the wafer is very important in terms of the management of the product yield of the semiconductor device. The defects can be checked by etching the wafer.

### DISCLOSURE OF INVENTION

### Technical Problem

The embodiment provides an etching treatment apparatus capable of effectively performing an etching process to check the defects of a wafer.

### Solution to Problem

According to the embodiment, there is provided an etching treatment apparatus including a crucible to receive a wafer, a wafer jig part having a groove into which the wafer is seated, and a size adjusting part inserted into the groove while making contact with the edge of the wafer.

### Advantageous Effects of Invention

As described above, the etching treatment apparatus according to the embodiment includes the wafer jig part in which the edge of the wafer can be seated. When the wafer is etched, only one side of the wafer can be prevented from being etched. In other words, since all sides of the wafer are etched, the wafer can be uniformly etched. In addition, the wafer can be prevented from being damaged due to the face error of the wafer.

The wafer jig part has a plurality of grooves therein, and a plurality of wafers can be inserted into the grooves. In other words, the wafers can be simultaneously etched. Therefore, the cost and the time of the etching process can be saved.

In addition, after the etching process has been finished, the wafer can be rapidly pulled out. Accordingly, the wafer can be prevented from being excessively etched. In addition, when the wafer is pulled out of the crucible, the wafer can be prevented from being damaged.

Thereafter, the wafer can be more conveniently pulled out. In other words, a worker can pull the wafer out by lifting the wafer jig part without directly making contact with a highly toxic solution.

In addition, the etching treatment apparatus according to the embodiment includes the size adjusting part. The size adjusting part allows the wafer to be stably seated in the groove according to the size of the wafer. Therefore, the wafer can be prevented from being out of the groove or moving.

Therefore, the etching treatment of the wafer can be effectively performed.

### BRIEF DESCRIPTION OF DRAWINGS

FIG. 1 is an exploded perspective view showing an etching treatment apparatus according to the embodiment;

FIG. 2 is a sectional view taken along line A-A′ of FIG. 1;

FIG. 3 is a plan view showing a wafer jig part;

FIG. 4 is a perspective view showing a size adjusting part; and

FIG. 5 is a flowchart showing an etching treatment process.

### MODE FOR THE INVENTION

In the description of the embodiments, it will be understood that, when a layer (or film), a region, a pattern, or a structure is referred to as being “on” or “under” another layer (or film), another region, another pad, or another pattern, it can be “directly” or “indirectly” on the other layer (or film), region, pad, or pattern, or one or more intervening layers may also be present. Such a position of the layer has been described with reference to the drawings.

The thickness and size of each layer (film), region, pattern, or structure shown in the drawings may be exaggerated, omitted or schematically drawn for the purpose of convenience or clarity. In addition, the size of each layer (film), region, pattern, or structure does not utterly reflect an actual size.

Hereinafter, the embodiment of the disclosure will be described in detail with reference to accompanying drawings.

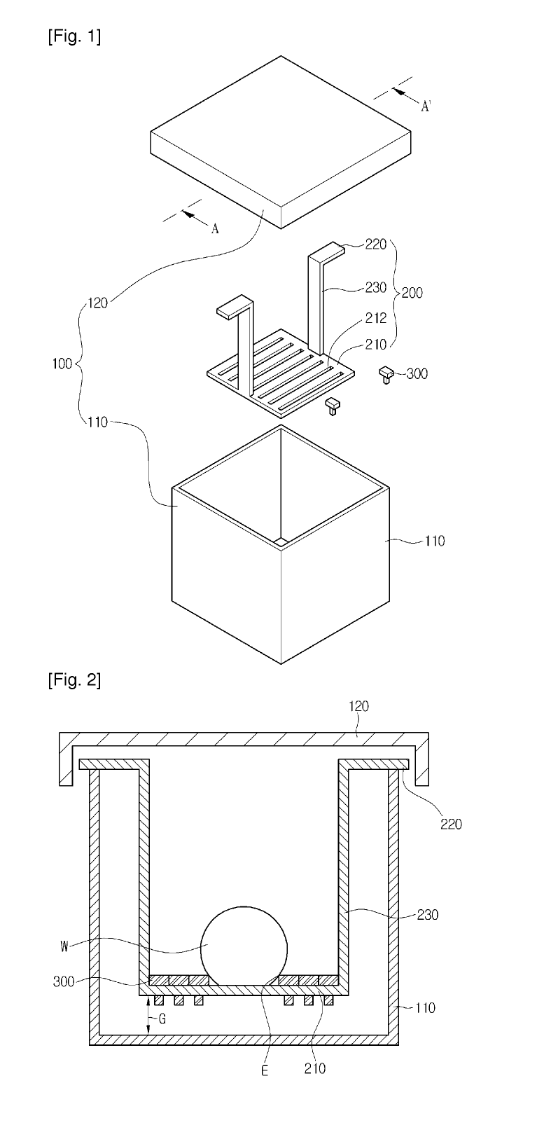

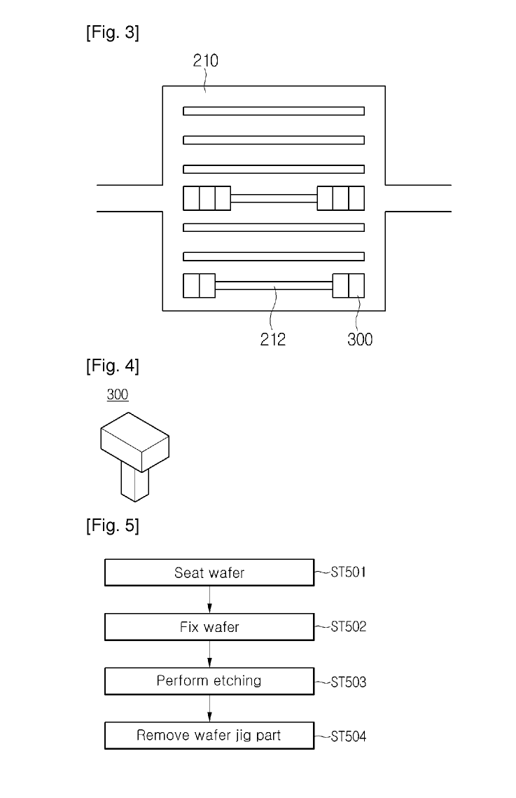

Hereinafter, an etching treatment apparatus according to the embodiment will be described in detail with reference to FIGS. 1 to 3. FIG. 1 is an exploded perspective view showing the etching treatment apparatus according to the embodiment, and FIG. 2 is a sectional view taken along line A-A′ of FIG. 1. FIG. 3 is a plan view showing a wafer jig part, and FIG. 4 is a perspective view showing a size adjusting part.

Referring to FIGS. 1 to 4, the etching treatment apparatus according to the present embodiment includes a crucible 100 and a wafer jig part 200 into which wafers W are inserted.

The crucible 100 includes a receiving part 110 to receive the wafers W and a cover part 120 to close the receiving part 110. The receiving part 110 may have a predetermined thickness to receive the wafers W. In the receiving part 110, the wafers W may be etched.

The cover part 120 may be positioned on the receiving part 110. The cover part 120 may close the receiving part 110.

Referring to FIG. 2, a space may be provided between the receiving part 110 and the cover part 120. Gas generated during the etching process may be discharged through the space. However, the embodiment is not limited thereto. In other words, if a gas discharging part is additionally provided, the receiving part 110 may adhere to the cover part 120.

The crucible 100 may include metal such as nickel (Ni). Accordingly, the crucible 100 can be prevented from being corroded or damaged by an etchant. Therefore, the crucible 100 may include various materials to protect the crucible 100 from a highly-toxic etchant.

Thereafter, the wafer jig part 200 is positioned in the crucible 100.

The wafer jig part 200 may have a thickness the same as that of the crucible 100. In addition, the wafer jig part 200 may include a material the same as that of the crucible 100. Therefore, the wafer jig part 200 can be prevented from being corroded or damaged by the etchant. Accordingly, the wafer jig part 200 can be repeatedly used.

The wafer jig part 200 includes a support part 210, into which the wafers W are inserted, a locking part 220 locked with the crucible 100, and a connection part 230 to connect the support part 210 to the locking part 220.

The support part 210 may be provided therein with grooves 212 into which the wafers W are seated. An edge E of the wafer W may be seated in the groove 212. In other words, two facing sides of the wafer W may be provided perpendicularly to the floor of the crucible 100. Therefore, when the wafer W is etched, only one side of the wafer W can be prevented from being etched. In other words, since all sides of the wafer W are etched, the wafer W can be uniformly etched. In addition, the wafer W can be prevented from being damaged due to the face error of the wafer W.

According to the related art, when a wafer is etched, the wafer is etched without installing a special device in a crucible. Accordingly, one side of the wafer to be etched makes contact with the floor of the crucible, and the side of the wafer making contact with the floor of the crucible is not smoothly etched. In addition, if the side of the wafer to be etched makes contact with the floor of the crucible due to the face error of the wafer, the surface of the wafer may be damaged.

Then, the support part 210 may include a plurality of grooves 212. Therefore, a plurality of wafers W may be inserted into the grooves 212. In other words, the wafers W can be simultaneously etched. Therefore, the cost of the etching process and the time of the etching process can be saved.

The locking part 220 is positioned at the upper portion of the crucible 100. In more detail, the locking part 220 is positioned at an upper end of the receiving part 110. The locking part 220 may allow the support part 210 to be stably positioned in the receiving part 110.

The locking part 220 may allow the support part 210 to be spaced apart from the floor of the receiving part 110 by a predetermined distance G. Accordingly, the etchant on the floor of the crucible 100 can be prevented from remaining on the wafer W. In other words, the locking part 220 can prevent the etchant from being instantly solidified on the floor of the receiving part 110 during the etching process of the wafer W.

In addition, after the etching process has been finished, a user can grip the locking part 220 and lift the wafer jig part 200 to pull the wafer W out. Therefore, after the etching process has been finished, the wafer W can be rapidly pulled out, so that the wafer W can be prevented from being excessively etched. In addition, the wafer W is rapidly removed, so that an additional process of removing the etchant due to the solidification of the etchant can be omitted, and the time to be spent in the additional process can be saved.

In addition, the locking part 220 can prevent the wafer W from being damaged when the wafer W is pulled out of the crucible 100.

In addition, the wafer W can be pulled out more conveniently. In other words, a worker can pull the wafer W out through the locking part 220 without directly making contact with the highly-toxic etchant.

Although not shown in drawings, a coupling device or a bonding device can be additionally provided so that the locking part 220 can be bonded to the upper end of the receiving part 110.

The connection part 230 may be interposed between the support part 210 and the locking part 220. The connection part 230 may connect the support part 210 to the locking part 220. The support part 210 may be positioned at the lower portion of the crucible 100 by the connection part 230.

As shown in FIG. 3, according to the embodiment, a size adjusting part 300 may be additionally provided. The size adjusting part 300 may fix the wafer W. The size adjusting part 300 may be inserted into the groove 212 of the support part 210. The size adjusting part 300 can stably seat the wafer W according to the size of the wafer W seated in the groove 212. A plurality of size adjusting parts 300 may be provided according to the size of the wafer W. In other words, if the wafer W has a small size, at least one size adjusting part 300 is inserted into the groove 212, so that the wafer W can be secured to the groove 212. Therefore, the wafer W can be prevented from being out of the groove 212 or moving.

The size adjusting part 300 may have various sizes. Accordingly, the wafer W can be fixed by using size adjusting parts 330 having various sizes according to the size of the wafer W.

The size adjusting part 300 may include a material the same as that of the crucible 100 in order to prevent the size adjusting part 300 from being corroded due to the etchant.

However, the embodiment is not limited thereto, and the size adjusting part 300 can be omitted when the wafer W is stably seated in to the groove 212.

Hereinafter, the etching treatment process will be described with reference to FIG. 5.

FIG. 5 is a flowchart showing the etching treatment process.

Referring to FIG. 5, the etching treatment process includes a step of seating a wafer (step ST501), a step of fixing the wafer (step ST502), an etching step (step ST503), and a step of removing a wafer jig part (step ST504).

In the step of seating the wafer (step ST501), a wafer is seated in the support part of the wafer jig part. In other words, the wafer may be seated in the groove formed in the support part. A plurality of wafers can be seated in the groove according to the number of the wafers.

Thereafter, in the step of fixing the wafer (step ST502), the wafer may be fixed depending on the size of the wafer. In other words, the wafer can be prevented from being out of the groove or moving by mounting the size adjusting part in the groove. The wafer can be fixed according to the size or the shape of the size adjusting part.

Thereafter, in the etching step (step ST503), the etching process may be performed by allowing the etchant to reacting to the wafer at the high temperature. The wafer may be smoothly etched by seating the wafer in the wafer jig part.

Thereafter, in the step of removing the wafer jig part (step ST504), the etching process may be finished by lifting the locking part of the wafer jig part. In other words, the wafer jig part can be removed after the locking part has been lifted. Accordingly, the wafer can be removed conveniently.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. An etching treatment apparatus comprising:
a crucible to receive a wafer; and
a wafer jig part having a groove into which the wafer is seated.

2. The etching treatment apparatus of claim 1, wherein the wafer jig part has a plurality of grooves.

3. The etching treatment apparatus of claim 1, wherein a plurality of wafers are provided.

4. The etching treatment apparatus of claim 2, wherein an edge of the wafer is seated into each groove.

5. The etching treatment apparatus of claim 1, wherein two sides of the wafer facing each other are spaced apart form a bottom surface of the crucible.

6. The etching treatment apparatus of claim 2, wherein the wafer jig part comprises;
a support part to support the wafer;
a locking part locked with the crucible; and
a connection part to connect the support part to the locking part.

7. The etching treatment apparatus of claim 6, wherein the crucible comprises:
a receiving part to receive the wafer; and
a cover part to close the receiving part.

8. The etching treatment apparatus of claim 7, wherein the locking part is locked with an upper end of the receiving part.

9. The etching treatment apparatus of claim 6, wherein the support part has a groove.

10. The etching treatment apparatus of claim 6, wherein the support part is spaced apart from a floor of the crucible.

11. The etching treatment apparatus of claim 1, wherein the crucible includes metal.

12. The etching treatment apparatus of claim 1, wherein the wafer jig part has a thickness corresponding to a thickness of the crucible.

13. The etching treatment apparatus of claim 1, wherein the wafer jig part includes a material a same as a material of the crucible.

14. The etching treatment apparatus of claim 1, further comprising a size adjusting part inserted into the groove.

15. The etching treatment apparatus of claim 14, wherein the size adjusting part makes contact with an edge of the wafer.

16. The etching treatment apparatus of claim 14, wherein the size adjusting part includes a material a same as a material of the crucible.
